(19) United States
(12) Patent Application Publication
(10) Pub. No.: US 2026/0118463 A1
(43) Pub. Date: Apr. 30, 2026

(54) METHOD FOR OPERATING A MAGNETIC RESONANCE FACILITY, MAGNETIC RESONANCE FACILITY, ASSOCIATED CONTROL FACILITY AND ASSOCIATED STORAGE UNIT

(71) Applicant: Siemens Healthineers AG, Forchheim (DE)

(72) Inventor: Stefan Popescu, Erlangen (DE)

(21) Appl. No.: 19/369,223

(22) Filed: Oct. 25, 2025

(30) Foreign Application Priority Data
Oct. 25, 2024 (EP) 24208862

(51) Int. Cl. G01R 33/565; G01R 33/385

(52) U.S. Cl. CPC G01R 33/56563; G01R 33/385; G01R 33/56581

(57) ABSTRACT

A method for operating a magnetic resonance facility is provided. The method includes generating a magnetic field using a magnet system. Measurement information is captured by a magnetic sensor. The measurement information relates to a stray magnetic field present outside an acquisition area and resulting from the magnetic field and an interference field. The method includes determining interference information relating to the interference field using the measurement information. The method includes compensating for or reducing the interference field in the acquisition area by changing the magnetic field using the interference information. In order to determine the interference information, a modeling of the interference field takes place using the measurement information. For the modeling, a field model describing a vector field for the interference field is used.

This application claims the benefit of European Patent Application No. EP 24208862.3, filed on Oct. 25, 2024, which is hereby incorporated by reference in its entirety.

### BACKGROUND

The present embodiments relate to operating a magnetic resonance facility

Magnetic resonance facilities (e.g., magnetic resonance systems) are employed for the performance of imaging using a magnetic resonance tomography method, which may also be referred to as the nuclear spin tomography method. A central area of application in this regard relates to medical imaging, where, for example, pathological changes in the body (e.g., tumors) may be detected using magnetic resonance facilities. For this purpose, the interior of the body of the object (e.g., of the patient) is made visible slice by slice by employing high magnetic fields.

For the performance of the imaging, nuclear spins of the object under examination are aligned by a strong external magnetic field, which may also be referred to as a main magnetic field, and are excited by a magnetic alternating field for the precession about this alignment. The precession or return of the spins from this excited state into a state with lower energy generates in response a magnetic alternating field that is received via antennas. Specifically, in an acquisition area of the magnetic resonance facility in which the object to be examined or the patient is arranged, the main magnetic field is generated by the magnet facility. Further, using the magnet facility, a gradient field is generated in the acquisition area, which in the course of performing the imaging, enables the necessary position determination in the acquisition area. Using the main magnetic field, an alignment of the spins of the atomic nuclei of the hydrogen atoms in the body takes place, where a short radio-frequency pulse or radio waves is/are then generated by a radio-frequency antenna unit, providing that the alignment of the atomic nuclei changes briefly and thereby the magnetic alternating field arises. The correspondingly arising signals that are used in the course of imaging differ from the type of the respective tissue. With the help of the gradient fields, a position encoding is imprinted on the signals, which subsequently enables an assignment of the received signal to a position inside the acquisition area. The received signal is then evaluated, and a three-dimensional representation of the object under examination is provided. To receive the signal, local receiving antennas (e.g., local coils) of the radio-frequency antenna unit may be used. The acquisition area, which may be configured to be spherical in shape and may also be referred to as the “field of view” (FoV) of the magnetic resonance facility, may be located inside a patient tunnel of the magnetic resonance facility.

The problem here is interference from the magnetic field present in the acquisition room, which may impair the imaging. Deviations of this magnetic field from an ideal, homogeneous field should be mentioned in this respect. On the other hand, interference may be caused by ferromagnetic objects moving close to the acquisition room (e.g., passing motor vehicles, elevators, trams or subways). Such interference is to be considered or suppressed in order to prevent image artifacts such as signal gaps, fat saturation errors, or geometric image distortions. Particularly susceptible to this are low-field scanners, which work with magnetic field strengths of the main magnetic field of no more than about 0.5 tesla.

To counter this problem, the use of a superconducting coil to suppress this interference has been proposed, by which magnetic field shifts caused by external magnetic fields are compensated for. However, the associated, passively operating circuit may react quite slowly, which is problematic in terms of effective suppression of the interference. Further, this only compensates for a constant shift in the magnetic field strength of the main magnetic field, where compensation with respect to the higher-order portions would frequently also be desirable.

A further conceivable procedure for suppressing this external interference is described in EP 4 369 017 A1. According to this, a measurement of the magnetic field strength takes place, whereby a transfer function that specifies the relationship between the magnetic field at the sensor and the acquisition area is determined. A calibration of a time component of the transfer functions takes place using pulse excitation that is generated by an interference source (e.g., a calibration coil) arranged at a certain location and at a certain alignment. However, for the calibration of the transmission functions in the spatial area, such an excitation or such input signals that cover or cover all possible locations and alignments of an external magnetic interference source are to be provided. In practice, performing such a calibration is difficult and time-consuming.

A further concept with respect to the determination of a magnetic field generated by a magnetic resonance facility is described in EP 4 105 671 A1 and U.S. Pat. No. 11,953,572 B2. It is provided here that multiple magnetic vectors are detected at different positions of the magnetic field by a magnetic field sensor unit, where each of the magnetic vectors describes a magnitude and a direction of the magnetic field at the respective position. The magnetic field is determined by determining a model of a vector field based on the magnetic vectors.

As further technological background, mention may be made of printed publication U.S. Pat. No. 11,815,575 B2. This printed publication discloses a magnetic resonance imaging apparatus with a main field unit for generating a main magnetic field, a gradient coil assembly for generating a gradient field, a radio-frequency assembly for sending excitation signals and receiving magnetic resonance signals, and a sensor facility for ascertaining magnetic field information in an imaging area. The sensor facility includes multiple magnetic field sensors in the imaging area. Based on the sensor data, magnetic field information for the imaging area is calculated. A calibration measure and/or correction measure is performed as a function of the magnetic field information.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, an improved concept with respect to compensation for magnetic field interference present in an acquisition room is provided.

Using a magnetic resonance facility, imaging for capturing image data may be performed. The image data relates to an object that is arranged in an acquisition area of the magnetic resonance facility. The following acts are executed for the performance of the imaging: (i) generation of a facility magnetic field present in the acquisition area using a magnet facility of the magnetic resonance facility, where a disrupted magnetic field actually present in the acquisition area results from the facility magnetic field and at least one interference field, and where the interference field is caused by an interference object located outside the acquisition area; (ii) capture of at least one item of measurement information using at least one magnetic sensor, where the measurement information relates to a stray magnetic field present outside the acquisition area and resulting from the facility magnetic field and the at least one interference field; (iii) determination of at least one item of interference information relating to the at least one interference field using the at least one item of measurement information; and (iv) compensation for or reduction of the at least one interference field in the acquisition area by changing the facility magnetic field using the at least one item of interference information.

In accordance with the present embodiments, in determining at least one item of interference information, modeling at least one interference field takes place using at least one item of measurement information. For the modeling, a field model describing a vector field is used for the at least one interference field.

The present embodiments are based, for example, on the thought that conclusions with respect to the magnetic field actually present in the acquisition area may be drawn based on the measurement information. This permits the determination of the interference information, which is directed specifically to the interference field present in the acquisition area and may be used to compensate for or at least reduce the interference field (e.g., for partial compensation).

The generation of the facility magnetic field provided for in connection with act (i) takes place using the magnet facility. The magnet facility includes at least one, for example, superconducting coil, using which a magnetic field with at least approximately parallel field lines is generated in the acquisition area. The Earth's magnetic field, which is always present, may be a component or portion of the facility magnetic field. Since the facility magnetic field is not limited to the acquisition area, but also extends outside the acquisition area or the magnetic resonance facility, the facility magnetic field causes a corresponding opposite field in ferromagnetic objects located in the area of influence of this magnetic field. This causes a change in the magnetic field actually present in the acquisition area, so that the magnetic field differs from the facility magnetic field that was actually intended.

Thus, in act (ii), the measurement information that relates to the stray magnetic field outside the acquisition area or the magnetic resonance facility is captured. The stray magnetic field results from the facility magnetic field and the interference field. To capture the measurement information, measurement signals from the magnetic sensor are captured and evaluated or processed. Using the magnetic sensor, a magnetic field vector (e.g., magnetic vector) present at the location of the magnetic sensor may be captured. Using the magnetic sensor, a magnitude and a direction of the stray magnetic field may consequently be determined. Using the magnetic sensor, three numerical values may be captured, each of which indicates a magnitude of the stray magnetic field along one of the three Cartesian spatial directions. The magnetic sensor in accordance with this embodiment may be referred to as a vector magnetometer. The aspects explained in the above-mentioned printed publication EP 4 369 017 A1 with regard to the magnetic field sensors provided for therein may be transferred by analogy to the at least one magnetic sensor, which is provided for in the present embodiments.

In act (iii), the interference information is determined based on the measurement information. In one embodiment, there is provision for the performance of mathematical modeling of the interference field using the measurement information. This modeling is based, for example, on the circumstance or approach that, with respect to the interference field, there is a freedom of source relating to at least the acquisition area. This provides that on the side of the magnetic resonance facility, the interference field, which mainly consists of non-ferromagnetic materials, does not induce any electrical currents, and consequently, no magnetic dipoles (e.g., sources) are caused by the interference field either. For the field model describing the interference field, for which in the present case, a vector field is used, it thus follows that its divergence and its rotation yields zero. It further follows that the interference field is a harmonic vector field, for which the Laplace equation applies. In accordance with this, the use of the Laplace operator on the vector field describing the interference field yields the value zero. This starting point enables a simplified numerical or computational handling of the measurement and/or interference information (e.g., relating to possible approaches to the determination of the at least one item of interference information). Thus, as will be explained later in detail, known solutions for the Laplace equation may be used as a basis for this, so that to ascertain the at least one item of interference information, for example, only a linear system of equations is to be solved or a fit is to be performed.

In act (iv) of the method, for example, an adjustment is made of at least one performance parameter used to perform the imaging, where this adjustment causes the compensation for or reduction of the interference field in the acquisition area. Thus, parameters of the facility magnetic field depend on the performance parameters that are specifically changed or modified based on the interference information, such that the magnetic field actually present in the acquisition room, which results from the changed facility magnetic field and the at least one interference field, corresponds to the actually desired magnetic field in the acquisition room. Specifically, the performance parameters may first be specified such that the resulting, actual magnetic field in the acquisition area corresponds to the actually desired magnetic field in the absence of the interference field. The change in the performance parameters resulting from the at least one item of interference information causes a change in the facility magnetic field such that this, together with the at least one interference field, leads to the occurrence of the desired magnetic field in the acquisition area. An iterative procedure may be provided for this purpose.

The performance of the acts of the method of the present embodiments (e.g., the capture and evaluation of the at least one item of measurement information and, where applicable, the simultaneous capture of the image data) may take place continuously or cyclically at predetermined time intervals, so that the compensation for or reduction of the interference field in the acquisition area takes place in real time. This is advantageous since sources of the interference field, which are also referred to as interference objects and may, for example, be vehicles or elevators, may move along a trajectory, so that their relative position with respect to the magnetic resonance facility typically changes over time and during the performance of the imaging. This results in a change in the interference field over time.

The magnet facility may include at least one main field coil and at least one gradient coil assembly. In act (i), in the acquisition area, a main magnetic field is generated by the at least one main field coil and at least one gradient field using the at least one gradient coil assembly. The main magnetic field may be, in relation to the acquisition area, at least approximately homogenous and consequently includes at least approximately parallel field lines. Further, the gradient field causes, for example, linear rise in the magnetic field strength with respect to a spatial direction and thus a field gradient. As a result of this, a location or position determination within the acquisition area in the context of imaging is enabled. Three gradient coil assemblies may be provided, for example, so that a field gradient is generated with respect to each of the (e.g., Cartesian) spatial directions. A radio-frequency antenna unit of the magnet facility may be provided for the generation of the radio-frequency pulse or radio waves.

As already mentioned above, the measurement information representing a magnetic vector may be captured in act (ii) using the magnetic sensor or using each of the magnetic sensors. This provides that both a magnitude and a direction of the magnetic field present at the location of the respective magnetic sensor are determined with the capture of the measurement information. Specifically, the magnetic vector may include three (e.g., scalar) values, each of which relates to the strength of the stray magnetic field with respect to a Cartesian spatial direction. A sensitivity of the magnetic sensor may be sufficiently high so that measured values relating to the stray magnetic field may be captured with regard to a resolution that is below an amplitude of the typically present interference field.

In one embodiment, the at least one magnetic sensor used in act (ii) may be arranged on a wall or a ceiling or a floor of a room in which the magnetic resonance facility is located. In one embodiment, multiple magnetic sensors may be arranged at the corners of a (e.g., regular) polyhedron (e.g., at the corners of a cuboid). The polyhedron may have the geometry of the room in which the magnetic resonance facility is located. In one embodiment, the magnetic sensors are arranged in the corners of this room. For example, in the case of a cuboid room, a total of at least or exactly eight magnetic sensors may be used.

In one embodiment, in act (iii), based on the at least one item of measurement information, at least one adjusted item of measurement information that relates to the stray magnetic field present outside the acquisition area and adjusted with respect to the facility magnetic field is determined. In one embodiment, known parameters relating to the facility magnetic field may be used to perform the adjustment of the at least one item of measurement information. Consequently, the adjusted measurement information no longer relates to the stray magnetic field (e.g., the facility magnetic field and the interference field), but only to the interference field. For this purpose, the values relating to the known facility magnetic field may be present as facility information. The facility information may include a magnetic vector, relating to at least the position of the at least one magnetic sensor. The magnetic vector may include three (e.g., scalar) values, each of which relates to the strength of the facility magnetic field with respect to a Cartesian spatial direction. The determination of the at least one adjusted item of measurement information results in a simplification in the further processing of the adjusted measurement information.

In the context of one development, it may be provided that in order to determine the at least one adjusted item of measurement information, values relating to the known facility magnetic field are subtracted from values relating to the stray magnetic field that are present based on the at least one item of measurement information. With respect to the stray magnetic field, this procedure is based on the superposition principle or the superposition theory. For this purpose, it is assumed that the facility magnetic field causes a magnetic moment in the interference object due to the ferromagnetic properties of the interference object. The interference field is caused by this magnetic moment. Thus, the stray magnetic field results from a vector sum relating to the vector field describing the facility magnetic field and the vector field describing the interference field. Since the vector field describing the facility magnetic field is typically known, a subtraction, in which the facility magnetic field is deducted from the stray magnetic field, results in the vector field describing the interference field.

It is to be assumed that the at least one item of measurement information is the magnetic vector present at the position of the respective magnetic sensor, and includes three scalar values, where each of these values concerns the strength of the stray magnetic field with respect to one of the three Cartesian spatial directions. Further, it is to be assumed that the values relating to the known facility magnetic field are present as the facility information already mentioned. The facility information is at least one magnetic vector relating to the position of the at least one magnetic sensor. The magnetic vector includes three scalar values, where each of these values relates to the strength of the facility magnetic field with respect to one of the three Cartesian spatial directions. The subtraction may then take place in the context of a vector subtraction, in which the magnetic field strength of the facility magnetic field is subtracted from the magnetic field strength of the stray magnetic field with respect to each spatial direction.

With respect to act (iii), as already mentioned above, it is conceivable for the field model to describe a harmonic vector field. Further, the field model may be based on a functional development that includes spatially harmonic basic functions. Spatially harmonic basic functions may be referred to as “spatial harmonics” and are defined with respect to the three-dimensional, Cartesian space. For the approximation of the interference field, a finite series may be used. Thus, the function development used may include basic functions up to at most first order or up to at most second order.

The field model may be fitted to the at least one (e.g., adjusted) item of measurement information. In one embodiment, the coefficients assigned to the basic functions of the field models may be used as fit parameters that represent the at least one item of interference information. Thus, the corresponding solution approach may be described as a sum of basic functions, each of which has a factor or coefficient, which is a scalar value and is initially unknown. These coefficients, for example, represent the fit parameters to be ascertained in the regression analysis performed in the context of this form of embodiment. This provides that in the context of the fit, a compensatory calculation is performed, in which the model function is approximated with respect to the values for the coefficients to the at least one item of measurement information. This approximation may be performed by a chi-square minimization. The results obtained for the coefficients then represent the interference information.

In a simple case (e.g., alternatively to the procedure based on the performance of a fit), a linear system of equations may be established and solved by the field model and the at least one (e.g., adjusted) item of measurement information. The coefficients assigned to the basic functions of the field model are the unknowns of the system of equations that represent the at least one item of interference information. Thus, with a sufficient number of values for the measurement information, the above-mentioned approach of function development leads to a uniquely solvable, linear system of equations, the solution of which provides the at least one item of interference information.

With respect to the at least one field model, the at least one field model may include multiple separate (e.g., orthogonal) sub-models. For example, it is provided that only a sub-model relating to a main field direction of the magnetic resonance facility is used to determine the at least one item of interference information. This procedure is based on the fact that the portions of the interference field relating to both spatial directions perpendicular to the main field direction or the z-direction do not cause any relevant or significant interference with respect to the facility magnetic field and may therefore be disregarded. This reduces the number of parameters or items of interference information to be ascertained. As a result of this, the computational effort required is reduced.

For example, if the interference object causing the at least one interference field is an object that is located or moves not just once but frequently in the area of the magnetic resonance facility, the capture of at least one item of comparison information in this respect may be provided. Such an object may, for example, be an elevator of the medical facility in which the magnetic resonance facility is located, or a public transportation vehicle (e.g., a tram or a subway) that regularly operates in the vicinity of the magnetic resonance facility. Accordingly, the at least one item of comparison information relating to a temporal development of the at least one item of measurement information during the occurrence of a comparison interference field may be stored. In the case of the later occurrence of a further interference field, the temporal development of which corresponds to the comparison interference field, the at least one item of comparison information in the context of act (iii) is used to perform a plausibility check. Specifically, in a situation when the magnetic field facility is in a standby mode in which the magnetic field facility does not generate a gradient field, the comparison information may be determined. The comparison information may in principle be the measurement information itself or a variable derived therefrom, where in the case just mentioned, the interference field results only from the main magnetic field and the interference field or the comparison interference field. Analogously to the adjusted measurement information, an adjusted item of comparison information may then be ascertained (e.g., by a subtraction). The capture of the at least one item of comparison information may take place once, but, for example, also during the entire service life of the magnetic resonance facility (e.g., before or during the performance of imaging procedures).

The plausibility check may be carried out by comparing the measurement information (e.g., adjusted) with the comparison information (e.g., adjusted). Specifically, a temporal development of the measurement information may be compared with the temporal development of the comparison information, and based on this comparison, a conclusion may be drawn as to whether the current procedure is a repetitive procedure that was already present in the capture of the comparison information. If in this respect a correspondence is established, it may be assumed that the procedure underlying the formation of the interference field is the same as that during the capture of the comparison information. Any measurement errors relating to the measurement information may then be corrected. Specifically, strong deviations or singular outliers may be accordingly corrected for individual items of measurement information using the comparison information.

In one embodiment, in act (iv), the compensation for or reduction of the at least one interference field in the acquisition area takes place in that a portion of the magnetic field present in the acquisition area and generated by an at least one or the at least one gradient coil of the magnet facility is subjected to a (e.g., time-dependent) magnetic field change that is specified based on the at least one item of interference information. In accordance with this form of embodiment, the gradient field to be generated by the gradient coil is selectively changed by a particular deviation. This deviation results in the actually generated gradient field together with the interference field producing the gradient field actually to be generated, and consequently, the interference field is compensated for or attenuated.

Further, in one embodiment, the at least one gradient coil may include two field coils (e.g., for the at least one gradient coil to be composed of two field coils). The field coils are each energized by a separate power source that, for example, is a power amplifier, to generate the or a gradient field, such that the field coils are operated in a Maxwell mode. The energization of the field coils taking place in the context of the Maxwell mode is formed inversely and causes the generation of the gradient field. In the Maxwell mode, which is also referred to as the anti-Helmholtz mode, a magnetic field that has at least approximately constant field gradients is produced between the field coils, so that the field strength of the gradient field changes at least approximately linearly.

In one embodiment, a gradient offset is imposed on the energization taking place as part of the Maxwell mode, by which a linear portion of the interference field is compensated for or reduced. With respect to the above-mentioned function development, the coefficient relating to the first-order basic function (e.g., relating to the z-direction) is used. Further, using the gradient offset, it is possible to reduce or compensate for a deviation of the main magnetic field from an ideal, homogeneous magnetic field.

Additionally or alternatively, the field coils may additionally be operated in a Helmholtz mode, where the energization of the field coils occurring in the context of the Helmholtz mode is formed equidirectionally and causes the compensation for or reduction of a constant portion of the interference field. With respect to the above-mentioned approach relating to the function development, the coefficient relating to the basic zeroth-order function is used (e.g., relating to the z-direction). By energizing the field coils in the Helmholtz mode, a deviation of the facility magnetic field is reduced or compensated for with respect to a constant shift in the magnetic field strength that is present due to the interference field. In one embodiment, energization of the field coils takes place in a mixed mode that includes both a portion in accordance with the Maxwell mode and a portion in accordance with the Helmholtz mode, which are additively composed.

Further, the present embodiments relate to a magnetic resonance facility for performance of the method in accordance with the above description. Using the magnetic resonance facility, imaging for capturing image data may be performed. The image data relates to an object that is arranged in an acquisition area of the magnetic resonance facility. The magnetic resonance facility includes a magnet facility, by which a facility magnetic field present in the acquisition area may be generated. A disrupted magnetic field actually present in the acquisition area results from the facility magnetic field and at least one interference field. The interference field is caused by an interference object located outside the acquisition area. Using at least one magnetic sensor, at least one item of measurement information that relates to a stray magnetic field present outside the acquisition area and resulting from the facility magnetic field and the at least one interference field may be captured. Using a control facility, at least one item of interference information relating to the at least one interference field may be determined using the at least one item of measurement information. The control facility is configured to generate control signals and to output the control signals to the magnetic resonance facility such that the at least one interference field in the acquisition area may be compensated for or reduced by changing the facility magnetic field using the at least one item of interference information. The object of the present embodiments is achieved in the case of this magnetic resonance facility in that the control facility is configured, in order to determine the at least one item of interference information, to perform a mathematical modeling of the at least one interference field using the at least one item of measurement information. For the modeling, at least one field model describing a vector field for the at least one interference field is used. The at least one magnetic sensor may be a component of the magnetic resonance facility. Alternatively, the at least one magnetic sensor is a component separate with respect to the magnetic resonance facility. All features, advantages, and aspects explained in connection with the method of the present embodiments may equally be transferred to the magnetic resonance facility of the present embodiments and vice versa.

The control facility of the magnetic resonance facility of the present embodiments is thus embodied and designed to perform the acts provided for in connection with the method of the present embodiments explained above. This applies, for example, for the determination of the information provided for in the course of performing this method based on the signals of the at least one magnetic sensor. This may further apply for the evaluation or processing of these signals and/or information as well as for the generation of the control signals provided for in the course of generating the facility magnetic field.

Further, the present embodiments relate to a control facility for a magnetic resonance facility in accordance with the preceding passages of description, including a storage unit on which an executable computer program that is suitable for being read by a processing facility of the control facility is stored. The executable computer program hereby causes the processing facility to determine the at least one item of interference information relating to the at least one interference field using the at least one item of measurement information, and to generate the control signals and output the control signals to the magnetic resonance facility such that the at least one interference field is compensated for or reduced in the acquisition area by changing the facility magnetic field using the at least one item of interference information. All features, advantages, and aspects explained in connection with the method of the present embodiments may equally be transferred to the control facility of the present embodiments and vice versa.

The present embodiments also relate to a storage unit for a control facility in accordance with the preceding passage of description, where an executable computer program is stored on the storage unit. The executable computer program is suitable for being read by a processing facility of the control facility and hereby to cause the processing facility to: determine the at least one item of interference information relating to the at least one interference field using the at least one item of measurement information; and to generate the control signals and output the control signals to the magnetic resonance facility such that the at least one interference field is compensated for or reduced in the acquisition area by changing the facility magnetic field using the at least one item of interference information. All features, advantages, and aspects explained in connection with the method of the present embodiments, the magnetic resonance facility of the present embodiments, and the control facility of the present embodiments may equally be transferred to the storage unit of the present embodiments and vice versa.

### BRIEF DESCRIPTION OF THE DRAWINGS

FIG. 1 shows a flow diagram of an embodiment of a method;

FIG. 2 shows a schematic sketch of an embodiment of a magnetic resonance facility;

FIG. 3 shows a perspective representation of a room in which the magnetic resonance facility of FIG. 2 is located;

FIG. 4 shows a further perspective representation of the room in FIG. 3; and

FIGS. 5 and 6 show schematic representations of a gradient coil assembly of the magnetic resonance facility of FIG. 2 relating to different operating modes.

### DETAILED DESCRIPTION

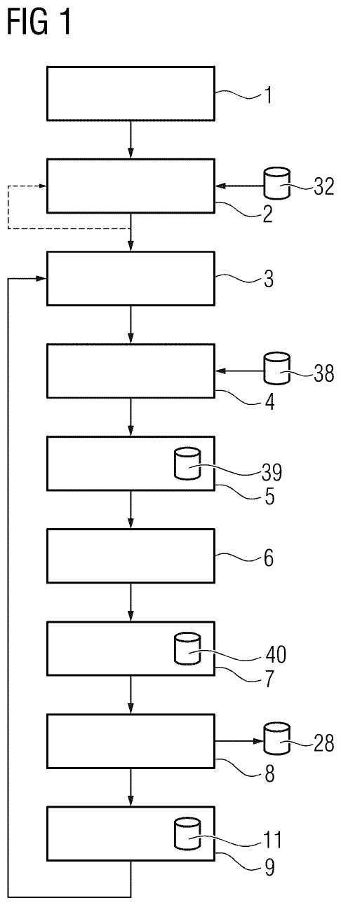

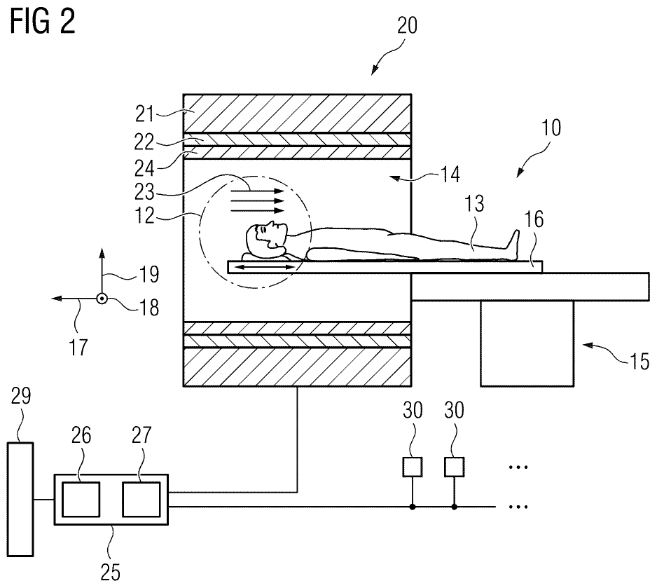

FIG. 1 shows a flow diagram of a computer-implemented method in accordance with an example embodiment. In the present case, the method includes acts 1-9 and is directed at the operation of an embodiment of a magnetic resonance facility 10 (e.g., a magnetic resonance system). FIG. 2 shows a schematic longitudinal section through the magnetic resonance facility 10. In the course of the performance of the method explained on the basis of FIG. 1, image data 11 that relates to an object 13 or a patient arranged in an acquisition area 12 of the magnetic resonance facility 10 is captured.

With reference to FIG. 2, the magnetic resonance facility includes 10 a tubular patient receiving area 14 or patient tunnel that includes a spherical acquisition area 12 that is also referred to as the “field of view.” The object 13 may be inserted into the patient receiving area 14 using a patient positioning apparatus 15. For this purpose, the patient positioning apparatus 15 has a patient table 16 that may be moved into the patient receiving area 14.

Relevant Cartesian spatial directions 17, 18, 19 in respect of the magnetic resonance facility 10 are hereafter introduced. A horizontal spatial direction 17, also referred to as the main field direction or z-direction, extends along a longitudinal direction of the cylindrical patient receiving area 14. A second, horizontal spatial direction 18, also referred to as the x-direction, extends perpendicular to the spatial direction 17. Further, a vertical spatial direction 19 is provided, which is perpendicular to the other two spatial directions 17, 18 and is also referred to as the y-direction.

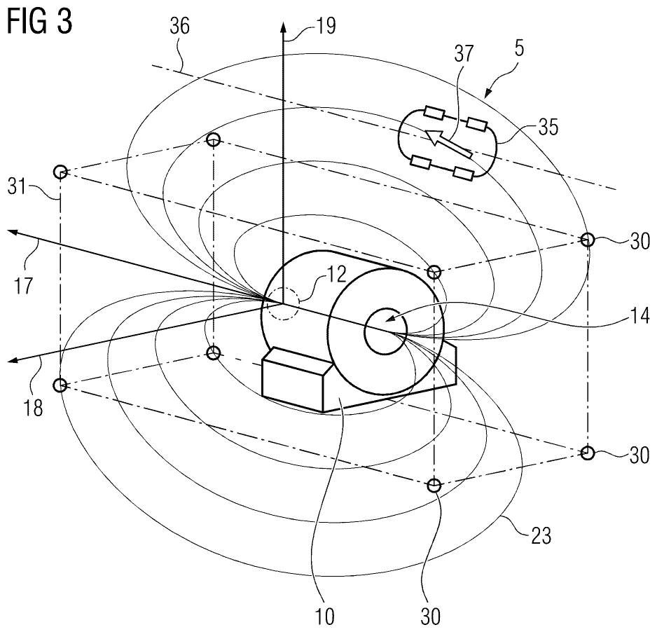

Further, the magnetic resonance facility 10 includes a magnet facility 20 that includes a main field coil 21 and three gradient coil assemblies 22, which in FIG. 2, are indicated only extremely schematically. Using the main field coil 21, an approximately homogeneous main magnetic field may be generated in the acquisition area 12, field lines of which are aligned along the main field direction and consequently spatial direction 17. Using the gradient coil assemblies 22, three gradient fields may be generated, by which field gradients relating to the spatial directions 17, 18, 19 are generated. The main magnetic field and the gradient fields together form a facility magnetic field 23 (e.g., a system magnetic field). The field lines of the facility magnetic field 23 are schematically indicated in FIGS. 2 and 3, where FIG. 3 shows a perspective representation of a room 31 in which the magnetic resonance facility 10 is located. Further, the magnet facility 20 includes a radio-frequency antenna unit 24, by which radio-frequency magnetic resonance sequences are irradiated into the acquisition area 12 and which is additionally designed to receive the resulting magnetic resonance signals. The magnetic resonance signals are the image data 11 or are used to ascertain the image data 11.

The magnetic resonance facility 10 further includes an embodiment of a control facility 25 (e.g., a controller) in accordance with an example embodiment, which includes an embodiment of a storage unit 26 in accordance with an example embodiment. The control facility 25 includes a processing facility 27 (e.g., including one or more processors), using which a computer program stored on the storage unit 26 may be executed. This execution in accordance with the following description causes the generation of control signals 28, by which the operation of the magnet facility 20 is controlled. Further, the control facility 25 is connected to a user interface 29 of the magnetic resonance facility 10. Using an input unit of the user interface 29, user-side control information such as imaging parameters may be specified by medical operators. Further, reconstructed magnetic resonance images may be displayed by a display unit of the user interface 29.

The acts of the method are explained below based on the flow diagram in FIG. 1. The first act 1 entails (e.g., once during the commissioning of the magnetic resonance facility 10) a calibration of magnetic sensors 30 of the magnetic resonance facility 10. The eight magnetic sensors 30 are arranged on a wall, a ceiling, or a floor of the room 31. The magnetic sensors 30 are arranged outside the acquisition area 12 or the magnetic resonance facility 10 (e.g., in the eight corners of the room 31, so that the magnetic sensors 30 are arranged in a cuboid manner to one another). For calibration, calibration signals are generated and output by the gradient coil assemblies 22 (e.g., chirp or triangular pulses). The measured values of the magnetic sensors 30 captured based on the calibration signals may, due to the knowledge of the parameters of the calibration signals and the knowledge of the relative positions and, where applicable, inclinations of the magnetic sensors 30 with respect to the reference system or the isocenter of the magnetic resonance facility 10, be used for the calibration of the magnetic sensors 30.

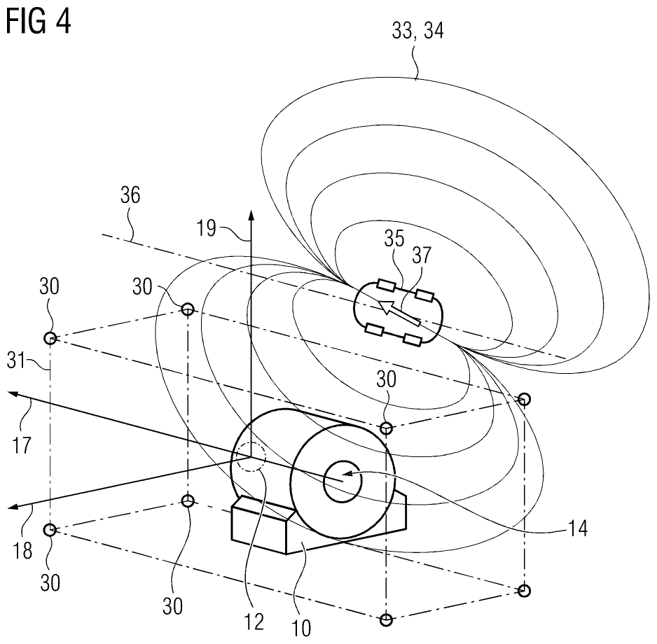

For the second act 2, it is assumed that the magnetic resonance facility 10 is in a standby mode, in which, using the main field coil 21, the main magnetic field is generated and the gradient coil assemblies 22 do not generate a gradient field, so that the facility magnetic field 23 results exclusively from the main magnetic field. In act 2, the capture of comparison information 32 takes place during the occurrence of an interference field 33, which is referred to as a comparison interference field 34 in connection with the capture of the comparison information 32. The facility magnetic field 23 as well as the interference field 33 cause a stray magnetic field present outside the magnetic resonance facility 10. The facility magnetic field 23 or the part of the stray magnetic field resulting from the facility magnetic field 23 may be assumed to be known and written as

$${\vec{B}}_{0 , G} ( \vec{r} , t ) = {\vec{B}}_{0} ( \vec{r} ) + {\vec{B}}_{G} ( \vec{r} , t ) ,$$

where the first term of this sum refers to the portion of the facility magnetic field 23 from the main magnetic field, and the second term refers to the portion of the facility magnetic field 23 from the gradient fields. The variables marked with a vector arrow are three-dimensional vectors, where the second term is additionally time-dependent. To illustrate the interference field 33 or the comparison interference field 34, reference is made to FIG. 4, which in principle corresponds to FIG. 3, but instead of the field lines of the facility magnetic field 23, shows the field lines of the interference field 33 or of the comparison interference field 34.

The interference field 33 or the comparison interference field 34 is caused by a ferromagnetic source moving in the vicinity of the magnetic resonance facility 10 or of the room 31, where the source is referred to below as an interference object 35 and in the present case is by way of example a motor vehicle moving along a trajectory 36. The interference object 35 may equally be an elevator or a public transportation vehicle such as a tram or a subway. Due to the ferromagnetic properties of the interference object 35, the facility magnetic field 23 induces a magnetic moment 37 in the interference object 35, which causes the occurrence of the interference field 33 or of the comparison interference field 34. In accordance with the superposition theory, the stray magnetic field, which may be captured by the magnetic sensors 30 using measurement technology, is additively composed of the facility magnetic field 23 and the interference field 33, so that

$${\vec{B}}_{0 , G , D} ( \vec{r} , t ) = {\vec{B}}_{0 , G} ( \vec{r} , t ) + {\vec{B}}_{D} ( \vec{r} , t )$$

applies, where the expression on the left-hand side refers to the stray magnetic field and, with respect of the right-hand side of this equation, the first term of this sum refers to the facility magnetic field 23 and the second term refers to the interference field 33 or the comparison interference field 34. Due to the fact that the magnetic resonance facility 10 is in standby mode, in which no gradient fields are present, the following applies for the stray magnetic field

$${\vec{B}}_{0 , G , D} ( \vec{r} , t ) = {\vec{B}}_{0} ( \vec{r} ) + {\vec{B}}_{G} ( \vec{r} , t ) + {\vec{B}}_{D} ( \vec{r} , t ) = {\vec{B}}_{0} ( \vec{r} ) + {\vec{B}}_{D} ( \vec{r} , t ) .$$

Using the magnetic sensors 30, measured values relating to the stray magnetic field are now determined, which are output to the control facility 25 and are processed by the processing facility 27. Using the magnetic sensors 30, a magnetic vector (e.g., three numerical values) is captured. Each of the numerical values indicates a magnitude of the measured stray magnetic field along one of the three spatial directions 17, 18, 19. The comparison interference field 34 relating to comparison information 32 is then determined by deducting from each of these numerical values the known part of the measured stray magnetic field, which is present based on the facility magnetic field 23 and is present as a known item of facility information. Consequently

$${\vec{B}}_{D} ( \vec{r} , t ) = {\vec{B}}_{0 , G , D} ( \vec{r} , t ) - {\vec{B}}_{0} ( \vec{r} )$$

is calculated and stored as the comparison information 32, which due to this subtraction, may be referred to as an adjusted item of comparison information. This procedure is now run through a number of (e.g., several) times in succession and at different points in time during the occurrence of the comparison interference field 34, so that based on the comparison information 32 determined in this way, a temporal development of the values of the comparison information 32 with respect to the occurrence of the comparison interference field 34 is present. This is indicated in FIG. 1 by the dashed arrow. In this case, a set of comparison information 32 is collected, which, as will be explained in detail below, may be used to check plausibility in the event of a recurrence of this or an at least similar interference.

The capture of the comparison information 32 provided for in the context of act 2 may be performed not just once during the commissioning of the magnetic resonance facility 10, but also during its service life (e.g., in the course of performing the capture of the image data 11, such as before the actual image capture takes place and the magnetic resonance facility is still in standby mode). Consequently, multiple sets of comparison information 32 are collected and stored, each of which is assigned to a specific procedure for the formation of the interference field 33.

In the third act 3, the gradient coil assemblies 22 generate the gradient fields. The resulting field gradients allow an assignment of the image data 11 captured in this way to corresponding positions inside the acquisition area 12.

In the fourth act 4, measurement information 38 relating to the currently present stray magnetic field is determined by the magnetic sensors 30. The measurement information 38 is, in accordance with what has already been explained in connection with the determination of the comparison information 32, in each case a corresponding magnetic vector including three scalar values.

In the fifth act 5, adjusted measurement information 39 is determined based on the captured measurement information 38, such as based on a subtraction in accordance with

$${\vec{B}}_{D} ( \vec{r} , t ) = {\vec{B}}_{0 , G , D} ( \vec{r} , t ) - {\vec{B}}_{0 , G} ( \vec{r} , t ) .$$

The resulting, adjusted measurement information 39 consequently now relates exclusively to the interference field 33, where the first term on the right-hand side of this equation is present based on the measurement information 38, and relates to the measured stray magnetic field. The second term relates to the facility magnetic field 23. In this case, the values for the facility magnetic field 23 relating to the positions of the magnetic sensors 30 based on the parameters by which the magnet facility 20 is operated are known as the above-mentioned facility information. This procedure too is based on the superposition theory, in accordance with which the stray magnetic field is additively composed of the facility magnetic field 23 and the interference field 33.

In the next, optional act 6 of the method, using the adjusted comparison information 32, a plausibility check relating to the adjusted measurement information 39 takes place. For this purpose, it is assumed that acts 3-9 have already been run through multiple times in succession, so that with respect to the adjusted measurement information 39, a temporal development is present. Consequently, act 6 is not performed when these acts are run through for the first time. Thus, the temporal progression relating to the adjusted measurement information 39 is compared with the temporal progression relating to the adjusted comparison information 32. If this comparison shows that these temporal progressions correspond to one another, then, it is to be assumed that the procedure that led to the presence of the comparison interference field 34 is the same procedure that is currently leading to the presence of the interference field 33. For example, this may be a procedure in which the interference object 35 causing the interference field 33 is an elevator moving along the room 31 or a tram or subway. In this case, large deviations in individual, adjusted measurement information 39 are corrected accordingly using the comparison information 32.

In the seventh act 7, interference information 40 relating to the currently present interference field 33 is determined based on the adjusted measurement information 39. For this purpose, a mathematical modeling of the interference field 33 takes place on the assumption or approach that the interference field 33 is a harmonic field, which, relating to at least the acquisition area 12, is a source-free field. Thus, the interference field 33 may be described by a vector field, which satisfies the Laplace equation

$$Δ {\vec{B}}_{D} ( \vec{r} , t ) = ( ∇ \cdot ∇ ) {\vec{B}}_{D} ( \vec{r} , t ) = 0 ,$$

where Δ refers to the Laplace operator. To determine the interference information 40, an approach now takes place, such that the field model used is based on a function development, so that with respect to the three spatial directions 17, 18, 19, the following relationships apply:

$${B}_{D , x} = {\sum }_{h = 1}^{H} {C}_{x , h} \cdot {SH}_{h} ( \vec{r} )$$

$${B}_{D , γ} = {\sum }_{h = 1}^{H} {C}_{y , h} \cdot {SH}_{h} ( \vec{r} )$$

$${B}_{D , z} = {\sum }_{h = 1}^{H} {C}_{z , h} \cdot {SH}_{h} ( \vec{r} )$$

In this case, C_{x,h}, C_{y,h}, and C_{z,h} refer to the coefficients assigned to the spatially harmonic basic functions SHₕ, where these basic functions SHₕ defined on the three-dimensional, Cartesian space are frequently also referred to as “spatial harmonics”. As shown, the field model used includes three separate, orthogonal sub-models that are specified by the aforementioned equations.

With respect to this approach, basic functions may be used up to at most a first order or may be taken into account, so that H=4 applies. In this case, the measured values of the eight magnetic sensors 30 are in principle sufficient to ascertain the unknown coefficients. It is also conceivable for basic functions to be used up to at most a second order or to be taken into account, so that H=9 applies. In this case, the measured values of nine magnetic sensors 30 would be required to ascertain the unknown coefficients C_{x,h}, C_{y,h}, and C_{z,h}. Also, to reduce the number of magnetic sensors 30 required to ascertain the unknown coefficients, only the third of the aforementioned equations may be used, so that with respect to the determination of the interference information 40, only an evaluation of the main field direction or z-direction (e.g., with respect to the spatial direction 17) takes place and only the coefficients C_{z,h} are ascertained.

In addition, the specific Cartesian expressions for the basic functions SHₕ are indicated below. Thus, for the zeroth order, SH₁ (x,y,z)=1. Further, for the first order, SH₂ (x,y,z)=x, SH₃ (x,y,z)=y, and SH₄ (x,y,z)=z. Further, for the second order, SH₅ (x,y,z)=xy, SH₆ (x,y,z)=zy, SH₇ (x,y,z)=2z²−x²−y², SH₈ (x,y,z)=xz, and SH₉ (x,y,z)=x²−y².

To ascertain the coefficients C_{x,h}, C_{y,h}, and C_{z,h}, a fit (e.g., a regression analysis) takes place using the control facility 25 using the function development as well as the adjusted measurement information 39. Further, it is conceivable, provided that the number of magnetic sensors 30 used is sufficiently high, for a linear system of equations to be established based on the approach explained above, which may be solved accordingly by the control facility 25. In this case, the determination of the coefficients C_{x,h}, C_{y,h}, and C_{z,h} results in a model describing the interference field 33.

In the eighth act 8, the control signals 28 are generated by the control facility 25 and are output to the magnet facility 20, such that the interference field 33 is compensated for or at least reduced in the acquisition area 12. For this purpose, a modification or adaptation of the facility magnetic field 23 using the interference information 40 is performed in accordance with the following explanation. For this purpose, reference is made exclusively to the main field direction or the spatial direction 17, where the same applies analogously for the two spatial directions 18, 19. Thus, the compensation for or at least reduction of the interference field 33 in the acquisition area 12 using the gradient coil assemblies 22 takes place, such that the portion of the magnetic field present in the acquisition area 12 generated by this is subjected to a time-dependent magnetic field change, which is specified based on the interference information 40.

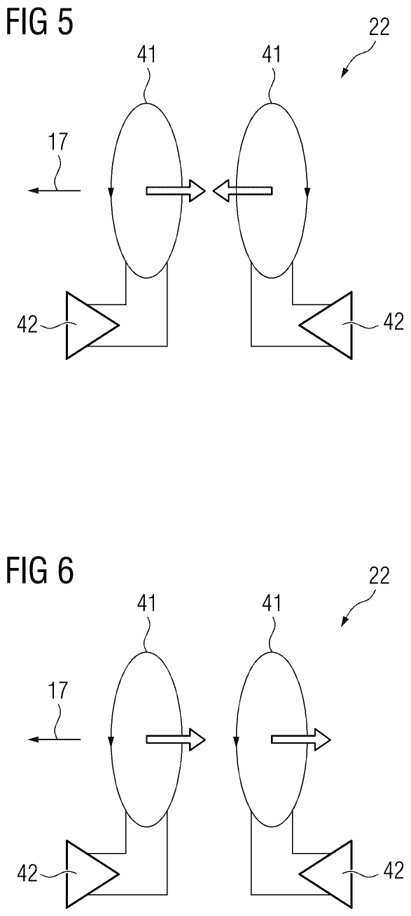

FIGS. 5 and 6 each show a schematic view of one of the gradient coil assemblies 22 (e.g., those by which the field gradient relating to the spatial direction 17 is generated). For both the other gradient coil assemblies 22, the following explanation applies analogously. Thus, the gradient coil assembly 22 is composed of two field coils 41 arranged parallel and collinear to one another. Each of the field coils 41 is energized separately by a separate power source 42 (e.g., a power amplifier in each case) based on the control signals 28. In this case, the field coil 41 is operated in accordance with a mixed mode, which represents a mixed form of a Maxwell mode indicated in FIG. 5 and a Helmholtz mode indicated in FIG. 6.

With respect to the Maxwell mode, there is an inverse energization of the field coils 41 for the generation of the gradient field. The portion of current flowing through the field coils 41 in this respect is referred to by I_{z,grad}. This portion is subject to a gradient offset referred to by I_{z,offset}, using which the linear portion of the interference field 33 is compensated for or at least reduced. The gradient offset I_{z,offset} results from the determined value for the coefficient C_{z,h=4}.

With respect to the Helmholtz mode, an equidirectional energization of the field coils 41 occurs. Using the corresponding portion of the energization, the compensation for or at least the reduction of a zeroth-order portion of the interference field 33 (e.g., a constant portion) is caused. This portion, referred to by I_{z,shift}, is ascertained with respect to the control information 40 from the determined value for which C_{z,h=1} results. Thus, overall, the currents I₁ and I₂ of both the field coils 41 result in

$${I}_{1} = {I}_{z , grad} ( t ) + {I}_{z , offset} + {I}_{z , shift}$$

$$and$$

$${I}_{2} = - {I}_{z , grad} ( t ) - {I}_{z , o f f s e t} + {I}_{z , shift} .$$

In the ninth act 9, the image data 11 is captured by the radio-frequency antenna unit 24. The acts 3-9 are now run through repeatedly until all required image data 11 has been captured. The acts 3-8 are run through consecutively and cause any temporal change in the interference field 33 to be taken account of.

In addition, it is noted that the information 38, 39, 40 captured in the course of the above-described performance of method acts 3-9 (e.g., the adjusted measurement information 39) may be stored as a further set of comparison information 32, which, in accordance with the above description, may be used for plausibility checks if interference occurs subsequently.

Further, it is also noted that the procedure of the present embodiments may also be applied if multiple interference objects 35 are located in the vicinity of the magnetic resonance facility 10. In this case, accordingly, multiple interference fields 33 are present. Due to the above-mentioned freedom of sources of the interference fields, it is possible to map these jointly by the modeling described above.

Independent of the grammatical term usage, individuals with male, female, or other gender identities are included within the term.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for operating a magnetic resonance system, wherein, using the magnetic resonance system, imaging for capturing image data is performable, the image data relating to an object that is arranged in an acquisition area of the magnetic resonance system, the method comprising:
generating a facility magnetic field present in the acquisition area using a magnet system of the magnetic resonance system, wherein a disrupted magnetic field actually present in the acquisition area results from the facility magnetic field and at least one interference field, wherein the interference field is caused by an interference object located outside the acquisition area;
capturing at least one item of measurement information using at least one magnetic sensor, wherein the at least one item of measurement information relates to a stray magnetic field present outside the acquisition area and resulting from the facility magnetic field and the at least one interference field;
determining at least one item of interference information relating to the at least one interference field using the at least one item of measurement information; and
compensating or reducing the at least one interference field in the acquisition area, the reducing comprising changing the facility magnetic field using the at least one item of interference information,
wherein determining the at least one item of interference information comprises modeling the at least one interference field using the at least one item of measurement information, and
wherein for the modeling, a field model describing a vector field for the at least one interference field is used.

2. The method of claim 1, wherein the magnet system comprises at least one main field coil and at least one gradient coil assembly,
wherein the generating comprises:
generating an at least approximately homogeneous main magnetic field in the acquisition area using the at least one main field coil; and
generating at least one gradient field using the at least one gradient coil assembly.

3. The method of claim 1, wherein the capturing comprises capturing the measurement information representing a magnetic vector using the at least one magnetic sensor, and
wherein the magnetic vector comprises three scalar values, each of which relates to a strength of the stray magnetic field with respect to a Cartesian spatial direction.

4. The method of claim 1, wherein the at least one magnetic sensor is arranged on a wall, a ceiling, or a floor of a room, in which the magnetic resonance system is located.

5. The method of claim 4, wherein the at least one magnetic sensor is arranged in a corner of the room, in which the magnetic resonance system is located.

6. The method of claim 1, wherein based on the at least one item of measurement information, at least one adjusted item of measurement information that relates to the stray magnetic field present outside the acquisition area is determined and adjusted with respect to the facility magnetic field.

7. The method of claim 6, wherein determining the at least one adjusted item of measurement information comprises subtracting values relating to the known facility magnetic field from values relating to the stray magnetic field that are present based on the at least one item of measurement information.

8. The method of claim 1, wherein the field model describes a harmonic vector field and is based on a function development that comprises spatially harmonic basic functions, up to at most the first order or up to at most the second order, and
wherein:
the field model is fitted to the at least one item of measurement information, wherein coefficients assigned to the spatially harmonic basic functions of the field model are used as fit parameters that represent the at least one item of interference information;
using the field model and the at least one item of measurement information, a linear system of equations is established and solved, wherein the coefficients assigned to the spatially harmonic basic functions of the field model are unknowns of the system of equations that represent the at least one item of interference information.

9. The method of claim 1, wherein the field model comprises multiple separate sub-models, and
wherein to determine the at least one item of interference information, only one sub-model of the multiple separate sub-models is used, the one sub-model relating to a main field direction of the magnetic resonance system.

10. The method of claim 1, further comprising:
storing at least one item of comparison information relating to a temporal development of the at least one item of measurement information during an occurrence of a comparison interference field; and
using, during a subsequent occurrence of a further interference field, temporal development of which corresponds to the comparison interference field, the at least one item of comparison information in the context of the determining of the at least one item of interference information, such that a plausibility check is performed.

11. The method of claim 1, wherein in the compensating, the compensation for or reduction of the at least one interference field in the acquisition area takes place in that a portion of the magnetic field present in the acquisition area and generated by at least one gradient coil assembly of the magnet system is subjected to a magnetic field change that is specified based on the at least one item of interference information.

12. The method of claim 11, wherein the at least one gradient coil assembly comprises two field coils, each of which is energized by a separate current source, configured to generate a gradient field, such that the two field coils are operated in a Maxwell mode, wherein the energization of the two field coils taking place in the context of the Maxwell mode is formed inversely and causes the generation of the gradient field.

13. The method of claim 12, wherein:
the energization taking place in the context of the Maxwell mode is subjected to a gradient offset, by which a linear portion of the interference field is compensated for or reduced;
the two field coils are additionally operated in a Helmholtz mode, wherein the energization of the field coils taking place in the context of the Helmholtz mode is formed equidirectionally and causes the compensation for or reduction of a constant portion of the interference field; or
a combination thereof.

14. A magnetic resonance system configured to perform imaging for capturing image data that relates to an object that is arranged in an acquisition area of the magnetic resonance system, the magnetic resonance system comprising:
a magnet system, by which a system magnetic field present in the acquisition area is generatable, wherein a disrupted magnetic field actually present in the acquisition area results from the system magnetic field and at least one interference field, wherein the at least one interference field is caused by an interference object located outside the acquisition area,
at least one magnetic sensor configured to capture at least one item of measurement information that relates to a stray magnetic field present outside the acquisition area and resulting from the system magnetic field and the at least one interference field;
a controller configured to:
determine at least one item of interference information relating to the at least one interference field using the at least one item of measurement information;
generate control signals and output the control signals to the magnetic resonance system, such that the at least one interference field is compensatable for or reduced in the acquisition area by changing the system magnetic field using the at least one item of interference information;
in order to determine the at least one item of interference information, perform a modeling of the at least one interference field using the at least one item of measurement information,
wherein for the modeling, a field model describing a vector field for the at least one interference field is used.

15. A controller for a magnetic resonance system, the controller comprising:
one or more processors;
a storage unit that stores a computer program executable by the one or more processors to:
determine at least one item of interference information relating to at least one interference field using the at least one item of measurement information; and
generate control signals and output the control signals to the magnetic resonance system, such that the at least one interference field is compensated for or reduced in an acquisition area by changing a system magnetic field using the at least one item of interference information.

16. A storage unit for a controller, the storage unit comprising:
a non-transitory computer-readable storage medium that stores an executable computer program executable by one or more processors to:
determine at least one item of interference information relating to at least one interference field using at least one item of measurement information; and
generate control signals and output the control signals to a magnetic resonance system, such that the at least one interference field is compensated for or reduced in an acquisition area by changing a system magnetic field using the at least one item of interference information.
